(19) United States
(12) Patent Application Publication
(10) Pub. No.: US 2026/0219231 A1
(43) Pub. Date: Jul. 30, 2026

(54) A METHOD OF PATTERNING A TWO-DIMENSIONAL MATERIAL FOR THE USE IN THE MANUFACTURE OF AN ELECTRONIC DEVICE

(71) Applicant: PARAGRAF LIMITED, Somersham (GB)

(72) Inventor: Liam McDonnell, Somersham (GB)

(73) Assignee: PARAGRAF LIMITED, Somersham (GB)

(21) Appl. No.: 19/149,024

(22) PCT Filed: Jan. 5, 2024
(86) PCT No.: PCT/EP2024/050217

§ 371 Date: Jul. 17, 2025

(30) Foreign Application Priority Data
Jan. 19, 2023 (GB) 2300792.5

(51) Int. Cl. G01N 27/414; H10D 62/80; H10P 14/20; H10P 50/64

(52) U.S. Cl. CPC G01N 27/4145; H10D 62/882; H10P 14/3434; H10P 50/642

(57) ABSTRACT

The present disclosure relates to a method of patterning a two-dimensional material for use in the manufacture of an electronic device, the method comprising: (i) providing a two-dimensional material layer (205) on a surface of a substrate (200); (ii) forming a molybdenum oxide layer (215) on the two-dimensional material layer (205) to provide a first stack comprised of the two-dimensional material and molybdenum oxide layers (205, 215), the molybdenum oxide layer (215) having a thickness of at least 0.1 nm; (iii) patterning the first stack to provide one or more patterned second stacks on the substrate; and (iv) etching at least a portion of the molybdenum oxide layer (215) from one or more of the patterned second stacks to expose an underlying portion of the two-dimensional material layer (205). The method is particularly suitable in the manufacture of gas sensors and biosensors.

The present invention relates to a method of patterning a two-dimensional material for use in the manufacture of an electronic device, in particular to a method comprising forming a molybdenum oxide layer on the two-dimensional material layer and subsequently etching at least a portion of said molybdenum oxide layer. The method may form part of the manufacture of an electronic device comprising said two-dimensional material layer and molybdenum oxide layer. The present invention is particularly suitable for use in the mass manufacture of an array of electronic devices.

Research into two-dimensional materials has grown rapidly since the isolation of graphene and its first use in electronic devices. Two-dimensional materials have the potential to exhibit unique and extraordinary electronic properties which are highly desirable for electronic applications. They also have unique optical and mechanical properties. However, production of such materials and their integration into electronic devices, particularly for large-scale mass manufacture, has proved challenging. Even at small-scale, manipulation of these exceptionally thin and sensitive materials is complex and known processes can be prone to introducing contamination and defects (both physical and chemical). Equally, these problems can lead to poorer reproducibility, in that device-to-device variability can be poor. The presence of contaminants in the final device can lead to poorer reliability and stability of the resulting electronic device.

As such, there remains a need for processes which address these problems in the prior art and which reduces the contamination of such two-dimensional materials in electronic device, or at least provide commercially viable alternatives thereto.

One particular class of electronic devices which are acutely susceptible to such problems include two-dimensional-material-based sensors, for example gas sensors and biosensors. Two-dimensional materials such as graphene are especially well suited for sensing applications due to their high sensitivity such that high defect control is essential in order to ensure accurate calibration as well as reliability and stability of performance.

UK Patent Application No. 2208400.8 (GB 2619704—the contents of which is incorporated herein in its entirety) relates to a thermally stable graphene-containing laminate in which a first metal oxide layer having a thickness of from 0.1 nm to 5 nm, formed of a transition metal oxide, is formed directly on a graphene layer structure, the first metal oxide layer having a work function of 5 eV or more.

UK Patent Application No. 2201466.6 (GB 2615341—the contents of which is incorporated herein in its entirety) relates to graphene sensors and a method of manufacture, the sample surface of said graphene sensors being devoid of photoresist.

AIP Advances 9, 055221 (2019) “Improved contact resistivity and enhanced mobility of metal-graphene FET by inserting ultra-thin MoOₓ layer at source/drain region” discloses inserting ultra-thin MoOₓ layer at source/drain region in traditional GFETs to improve contact properties between metal and graphene.

13^{th} IEEE International Conference on Solid-State and Integrated Circuit Technology (ICSICT), 2016, 830-832 “Improved contact properties of Metal/Graphene interface by inserting MoOx dielectric layer” discloses depositing MoOx at source/drain region can induce p-doping to graphene owing to its high work function and therefore reduce the contact resistances of metal and graphene to improve the electrical properties of graphene FETs.

US 2022/0262978 A1 relates to the growth and fabrication of optoelectronic devices using a graphene layer as a transparent and/or conducting electrode on a substrate.

CN 214254350 U relates to a near-infrared photodetector comprising tin-doped molybdenum oxide, said tin doping is said to reduce the bandgap and provide efficient absorption of near-infrared photons.

The present inventors developed the present invention with the aim of ameliorating the problems in the prior art, or to at least provide a commercially viable alternative thereto.

In accordance with a first aspect of the present invention, there is provided a method of patterning a two-dimensional material for use in the manufacture of an electronic device, the method comprising:
(i) providing a two-dimensional material layer on a surface of a substrate;
(ii) forming a molybdenum oxide layer on the two-dimensional material layer to provide a first stack comprised of the graphene and molybdenum oxide layers, the molybdenum oxide layer having a thickness of at least 0.1 nm;
(iii) patterning the first stack to provide one or more patterned second stacks on the substrate; and
(iv) etching at least a portion of the molybdenum oxide layer from one or more of the patterned second stacks to expose an underlying portion of the two-dimensional material layer.

The present disclosure will now be described further. In the following passages, different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous. As such, the features of the method described herein may equally be used to describe the products described herein, and vice versa.

The present invention relates to a method of patterning a two-dimensional material for use in the manufacture of an electronic device. That is, the present invention relates to a process that produces a patterned two-dimensional material on a substrate surface, the patterned two-dimensional material being suitable for use in the manufacture of an electronic device. As such, the present invention further relates to a method of manufacturing an electronic device comprising the method of patterning a two-dimensional material as described herein.

In a first step, the method comprises providing a two-dimensional material layer on a surface of a substrate. The present invention finds particular application in embodiments wherein the two-dimensional material layer comprises graphene, which is preferred for all aspects. Graphene, in particular monolayer graphene, exhibits unique and advantageous electronic properties due to its semi-metal band structure and, as such, its properties are particularly sensitive to impurities and therefore benefits greatly by the present method. Other suitable two-dimensional materials for use in the method includes mono-elemental two-dimensional materials such as silicene, germanene, borophene (whether doped or un-doped) though two-dimensional materials such as h-BN and transition metal dichalcogenides (TMDCs) such as MoS₂, WS₂ and MoSe₂ may be used. Methods of providing two-dimensional materials such as graphene are known in the art. Graphene is frequently manufactured by CVD on catalytic metal substrates, typically copper, and the graphene is then transferred to the desired substrate for electronic device fabrication (e.g. silicon). Other known methods include exfoliation along with the oxidation and reduction of graphite via graphene oxide.

A two-dimensional material layer (which may be referred to herein as a two-dimensional material layer structure, for example a graphene layer structure) preferably has from 1 to 10 monolayers of two-dimensional material. Preferably the two-dimensional material layer is comprised of a single monolayer. A preferred multilayer structure would have 2 or 3 monolayers. Preferably, all of the monolayers are of the same two-dimensional material (e.g. bilayer graphene), though in some embodiments, the layer structure may be a heterostructure. By way of example only, the two-dimensional material layer structure may be a sandwich of graphene between two layers of h-BN or a TMDC on graphene.

The two-dimensional material layer is provided on a substrate, preferably a non-metallic surface of a substrate. Preferably, the non-metallic surface upon which the two-dimensional material layer is provided is silicon (Si), silicon carbide (SiC), silicon nitride (Si₃N₄), silicon dioxide (SiO₂), sapphire (Al₂O₃), aluminium gallium oxide (AGO), hafnium dioxide (HfO₂), zirconium dioxide (ZrO₂), yttria-stabilised hafnia (YSH), yttria-stabilised zirconia (YSZ), magnesium aluminate (MgAl₂O₄), yttrium orthoaluminate (YAlO₃), strontium titanate (SrTiO₃), cerium oxide (Ce₂O₃), scandium oxide (Sc₂O₃), erbium oxide (Er₂O₃), magnesium difluoride (MgF₂), calcium difluoride (CaF₂), strontium difluoride (SrF₂), barium difluoride (BaF₂), scandium trifluoride (ScF₃), germanium (Ge), cubic boron nitride (c-BN) and/or a III/V semiconductor such as aluminium nitride (AlN) and gallium nitride (GaN).

In some embodiments, the substrate may consist of one such material. Preferably, the non-metallic surface is silicon, silicon nitride, silicon dioxide, sapphire, aluminium nitride, YSZ, scandium oxide, germanium and/or calcium difluoride. Preferably, the non-metallic surface is sapphire, yttria-stabilised zirconia, scandium oxide or calcium difluoride. In some preferred embodiments, the substrate comprises, or consists of, a first layer which provides the non-metallic surface and a support layer. Preferably, the support layer comprises silicon. A silicon support layer, includes a “pure” silicon wafer (essentially consisting of silicon, doped or undoped) or what may be referred to as a CMOS wafer which includes additional associated circuitry. A substrate may also comprise one or more layers (for example, regions or channels of embedded waveguide materials such as silicon nitride suitable for electro-optic modulators and photodetectors). The thickness of the support layer is generally much thicker that the thickness of the first layer thereon. Typically, the support layer has a thickness of 250 μm to 1.5 mm, for example from 400 μm to 1 mm. On the other hand, the thickness of the first layer of such a substrate is substantially thinner and may be formed on the support by epitaxy such as molecular beam epitaxy (MBE) or high temperature sputtering. Preferably, the thickness is at least 2 nm, preferably at least 5 nm and/or less than 500 nm, preferably less than 100 nm. Suitable ranges for the thickness of the first layer are preferably 5 nm to 100 nm, preferably 10 to 50 nm.

It is particularly preferred in the present invention that the two-dimensional material layer is provided on the surface of the substrate in the first step by directly forming the two-dimensional material layer on the surface by CVD. Forming the two-dimensional material directly on the substrate avoids steps such as transferring which can otherwise introduce impurities which risks negating the benefit of the invention. For example, direct formation avoids using transfer polymers, etching solutions and solvents. Forming may be considered synonymous with synthesising, manufacturing, producing and growing.

CVD refers generally to a range of chemical vapour deposition techniques, each of which involve vacuum deposition to produce thin film materials such as two-dimensional crystalline materials like graphene. Volatile precursors, those in the gas phase or suspended in a gas, are decomposed to liberate the necessary species to form the desired material, carbon in the case of graphene. CVD as described herein is intended to refer to thermal CVD such that the formation of graphene from the decomposition of a carbon-containing precursor is the result of the thermal decomposition of said carbon-containing precursor. A CVD layer formed directly on a surface can be distinguished from one transferred, due to the presence of metallic and other impurities.

Preferably, the method involves forming graphene by thermal CVD such that decomposition is a result of heating the carbon-containing precursor. Preferably, the temperature of the growth surface during CVD is from 700° C. to 1350° C., preferably from 800° C. to 1250° C., more preferably from 1000° C. to 1250° C. The inventors have found that such temperatures are particularly effective for providing graphene growth directly on the materials described herein by CVD. Preferably, the CVD reaction chamber used in the method disclosed herein is a cold-walled reaction chamber wherein a heater coupled to the substrate is the only source of heat to the chamber.

In a particularly preferred embodiment, the CVD reaction chamber comprises a close-coupled showerhead having a plurality, or an array, of precursor entry points. Such CVD apparatus comprising a close-coupled showerhead may be known for use in MOCVD processes. Accordingly, the method may alternatively be said to be performed using an MOCVD reactor comprising a close-coupled showerhead. In either case, the showerhead is preferably configured to provide a minimum separation of less than 100 mm, more preferably less than 25 mm, even more preferably less than 10 mm, between the surface of the substrate and the plurality of precursor entry points. As will be appreciated, by a constant separation it is meant that the minimum separation between the surface of the substrate and each precursor entry point is substantially the same. The minimum separation refers to the smallest separation between a precursor entry point and the substrate surface (i.e. the surface of the metal oxide layer). Accordingly, such an embodiment involves a “vertical” arrangement whereby the plane containing the precursor entry points is substantially parallel to the plane of the substrate surface (i.e. the growth surface).

The precursor entry points into the reaction chamber are preferably cooled. The inlets, or when used, the showerhead, are preferably actively cooled by an external coolant, for example water, so as to maintain a relatively cool temperature of the precursor entry points such that the temperature of the precursor as it passes through the plurality of precursor entry points and into the reaction chamber is less than 100° C., preferably less than 50° C. For the avoidance of doubt, the addition of precursor at a temperature above ambient does not constitute heating the chamber, since it would be a drain on the temperature in the chamber and is responsible in part for establishing a temperature gradient in the chamber.

Preferably, a combination of a sufficiently small separation between the substrate surface and the plurality of precursor entry points and the cooling of the precursor entry points, coupled with the heating of the substrate to with a decomposition range of the precursor, generates a sufficiently steep thermal gradient extending from the substrate surface to the precursor entry points to allow graphene formation on the substrate surface. As disclosed in WO 2017/029470, very steep thermal gradients may be used to facilitate the formation of high-quality and uniform two-dimensional material layers directly on non-metallic substrates, preferably across the entire surface of the substrate. The substrate may have a diameter of at least 5 cm (2 inches), at least 15 cm (6 inches) or at least 30 cm (12 inches). Particularly suitable apparatus for the method described herein include an Aixtron® Close-Coupled Showerhead® reactor and a Veeco® TurboDisk reactor.

Consequently, in a particularly preferred embodiment wherein the method of the present invention involves using a method as disclosed in WO 2017/029470, forming a graphene layer structure directly on a substrate by CVD comprises:
providing the growth substrate on a heated susceptor in a close-coupled reaction chamber, the close-coupled reaction chamber having a plurality of cooled inlets arranged so that, in use, the inlets are distributed across the growth surface and have constant separation from the substrate;
cooling the inlets to less than 100° C. (i.e. so as to ensure that the precursor is cool as it enters the reaction chamber);
introducing a carbon-containing precursor in a gas phase and/or suspended in a gas through the inlets and into the close-coupled reaction chamber; and
heating the susceptor to achieve a growth surface temperature of at least 50° C. in excess of a decomposition temperature of the precursor, to provide a thermal gradient between the substrate surface and inlets that is sufficiently steep to allow the formation of graphene from carbon released from the decomposed precursor;
wherein the constant separation is less than 100 mm, preferably less than 25 mm, even more preferably less than 10 mm.

In another particularly preferred embodiment wherein the method involves using a method as disclosed in WO 2019/138231 (the contents of which is incorporated herein in its entirety), forming a graphene layer structure directly on a substrate by CVD comprises:
providing the growth substrate on a heated susceptor in a reaction chamber, the reaction chamber having a plurality of inlets arranged so that, in use, the inlets are distributed across the growth surface and have constant separation from the substrate;
rotating the heated susceptor at a rotation rate of at least 600 rpm, preferably up to 3000 rpm;
introducing a carbon-containing precursor in a gas phase and/or suspended in a gas through the inlets and into the reaction chamber; and
heating the susceptor to achieve a growth surface temperature of at least 50° C. in excess of a decomposition temperature of the precursor;
wherein the constant separation is at least 12 cm, preferably up to 20 cm.

The most common carbon-containing precursor in the art for graphene growth is methane (CH₄). The inventors have found that it is preferable that the carbon-containing precursor used to form graphene is an organic compound, that is, a chemical compound, or molecule, that contains a carbon-hydrogen covalent bond, which comprises two or more carbon atoms. The carbon-containing precursor is preferably a C₃-C₁₀ organic compound consisting of carbon and hydrogen and, optionally, oxygen, nitrogen, fluorine, chlorine and/or bromine, even more preferably a C₆-C₉ organic compound. In a preferred embodiment, the precursor does not comprise a heteroatom, such that the precursor consists of carbon and hydrogen. In other words, preferably the carbon-containing precursor is a hydrocarbon, preferably an alkane. It is also preferable that the organic compound comprise at least two methyl groups (—CH₃). Particularly preferred organic compounds for use as carbon-containing precursors, and methods of forming graphene therefrom by CVD, are described in GB 2604377 (the contents of which is incorporated herein in its entirety).

The method further comprises a second step of forming a molybdenum oxide layer (e.g. MoO₃) on the two-dimensional material layer to provide a first stack comprised of the two-dimensional material and molybdenum oxide layers, the molybdenum oxide layer having a thickness of at least 0.1 nm, preferably at least 0.5 nm and/or at most 100 nm.

In a preferred embodiment, between steps (ii) and (iii) of forming the molybdenum oxide layer and patterning the first stack, the method further comprises forming a dielectric layer on the molybdenum oxide layer to provide a first stack comprised of the two-dimensional material, molybdenum oxide and dielectric layers. The dielectric layer is not particularly limited and may be a metal oxide, nitride or fluoride layer, preferably a metal oxide layer such as aluminium oxide, hafnium oxide, zinc oxide, titanium oxide, zirconium oxide, magnesium aluminate and/or YSZ.

The molybdenum oxide layer and/or the dielectric layers may be selectively deposited, for example using a shadow mask. Preferably, the molybdenum oxide layer and/or the dielectric layers are deposited on and across the wafer surface. The molybdenum oxide may be deposited using conventional means in the art, for example PVD techniques such as sputtering or evaporation (e.g. thermal evaporation) or atomic layer deposition (ALD).

The dielectric layer may be formed by sputtering, thermal evaporation, e-beam evaporation or ALD. Preferably, the dielectric layer is formed by ALD. ALD is technique known in the art that comprises the reaction of at least two precursors in a sequential, self-limiting manner. Repeated cycles to the separate precursors allow the growth of a layer in a conformal manner (i.e. uniform thickness across the entire surface) due to the layer-by-layer growth mechanism. For example, alumina is a particularly preferred dielectric and can be formed by sequential exposure to trimethylaluminium (TMA) and an oxygen source, preferably one or more of water (H₂O), O₂, and ozone (O₃).

As such, a preferred embodiment of the present invention is a method comprising:
(I) providing a two-dimensional material layer (preferably a graphene monolayer) on a surface of a substrate;
(II) forming a molybdenum oxide layer on the two-dimensional material layer, the molybdenum oxide layer having a thickness of at least 0.1 nm;
(III) forming a dielectric layer on the molybdenum oxide layer to provide a first stack comprised of the two-dimensional material, molybdenum oxide and dielectric layers;
(IV) patterning the first stack to provide one or more patterned second stacks on the substrate; and
(V) etching at least a portion of the molybdenum oxide layer from one or more of the patterned second stacks to expose an underlying portion of the two-dimensional material layer.

The desired nominal thickness of molybdenum oxide can be achieved through use of a Quartz Crystal Microbalance (QCM) during formation which provides the skilled person with an in-situ measurement of the amount of material deposited when carrying out the method. The thickness of the layer is therefore a mean average thickness of the layer. At thicknesses of 2 nm or less, the layer typically forms what may be known as “seeds” or “islands” without having formed a uniform layer. The thickness may then equally be readily determined by those skilled in the art using conventional techniques, for example, atomic force microscopy (AFM). Generally, a complete layer will form at greater thicknesses (e.g. more than 2 nm). In some embodiments, particularly where a dielectric layer is formed on the molybdenum oxide layer, the molybdenum oxide layer has a thickness of at most 5 nm, such a layer being suitable for seeding the formation of the dielectric layer. Thicker layers may be preferred to form a uniform layer to fully protect the underlying two-dimensional material. Preferably, the first stack (and/or each of the resulting one or more patterned second stacks) has a thickness of at least 5 nm, preferably at least 10 nm, and/or at most 100 nm, preferably at most 50 nm.

The method further comprises a third step of patterning the first stack to provide one or more patterned second stacks on the substrate, preferably an array of patterned second stacks across the substrate since such a method is suitable for use in the mass manufacture of electronic devices. The step of patterning the first stack (which may extend uniformly across the substrate) serves to pattern the two-dimensional material as desired for the intended application. Suitable shapes are known in the art. By way of example, for a transistor or a sensor the stack may be patterned into a rectangular shape, or for a Hall-sensor the stack may be patterned into a cross or any other known Hall-bar geometry.

Such a step of patterning may be performed using any conventional means in the art, e.g. microlithography such as photolithography. By employing a molybdenum oxide layer, the underlying portion of two-dimensional material is protected during the processing. For example, such a process may be described the steps of:
(a) applying a first photoresist to the first stack and patterning it to provide a first masked region;
(b) etching the molybdenum oxide layer and, when present, the dielectric layer, to retain only the molybdenum oxide and dielectric layers beneath the first masked region, exposing a portion of the two-dimensional material;
(c) plasma etching the exposed portion of the two-dimensional material to retain only the two-dimensional material beneath the first masked region; and
(d) removing the first photoresist.

As in conventional microfabrication processes, electrical contacts (e.g. metal) may be deposited during manufacture of an electronic device, for example using photolithography techniques.

The method further comprises a fourth step of etching at least a portion of the molybdenum oxide layer from one or more of the patterned second stacks to expose an underlying portion of the two-dimensional material layer, for example by photolithography. Where present, the corresponding portion(s) of dielectric layer on the molybdenum oxide layer are also etched. In some embodiments, all of the patterned second stacks are etched identically, for example in the manufacture of an array of identical devices.

Whilst it is known to pattern two-dimensional materials such as graphene by photolithography, this can leave organic polymer residues on the surface of the two-dimensional material which interfere with its electronic properties. The inventors had found that they can protect two-dimensional materials with a metal oxide layer and instead pattern the metal oxide layer (and two-dimensional material) by photolithography. However, similar problems could still be observed with residues of metal oxide when it is finally removed.

The inventors have found that by using a layer of molybdenum oxide as described herein, the efficiency with which the metal oxide can be etched and removed is greatly improved. Molybdenum oxide is generally more soluble in water/alkali than other metal oxides and its dissolution allows for quick and effective etching of the metal oxide during patterning reducing the risk of contamination of the sensitive two-dimensional material, in particular graphene. The molybdenum oxide layer may be etched using an aqueous solution, such as deionised water, or any conventional photolithography developer. In some preferred embodiments, the aqueous solution is acidic or alkaline (such as when a dielectric layer is also present), preferably comprising an alkali metal hydroxide. Where an alkaline solution is used, preferably the pH is from 8 to 10.

As such, the quality of the underlying two-dimensional material is maintained which is advantageous for sensors since it is the two-dimensional material that provides the sample surface for interacting with the species to be detected.

The inventors have found that photoresist materials are relatively complex, long chain organic polymers, which bind to the surface of two-dimensional materials due to π-π stacking and van der Waals forces, and saturate the surface preventing proper functionalisation and moreover impact the sensing function within the Debye length. Without wishing to be bound by theory, the inventors have also found that the molybdenum oxide has much lower adherence to the surface and, even if some of the oxide remains, these more inert traces are significantly less interfering with analyte detection than photoresist residues, leading to an improved device performance.

Such an advantage can be combined with the formation of better quality dielectric layers through the use of a seed layer of molybdenum oxide. Such seeded dielectric layers can be retained in the final electronic device. For example, such layers can be used in a sensor whereby the dielectric layer separates the contact(s) from the sample surface, or a transistor where the dielectric layer separates the graphene from the gate contact. In some preferred embodiments, the entirety of the molybdenum oxide and optional dielectric layers are etched away. That is, the present invention provides a method in which a two-dimensional material is formed across a wafer and then protected with a molybdenum oxide layer. Such an intermediate may be supplied to device manufacturers (either before or after patterning) and the protective molybdenum oxide coating quickly washed away without leaving residues for subsequent device fabrication incorporating a two-dimensional material. As such, the present disclosure also relates to the use of molybdenum oxide as a sacrificial layer to protect a two-dimensional material during the manufacture of an electronic device.

Without wishing to be bound by theory, it is believed that by using the present method to substantially avoid residues on the surface of the two-dimensional material, further layers may be deposited on the exposed two-dimensional material surface, such as electrical contacts or functionalising agents for a biosensor, with improved adhesion and electrical connectivity.

The present invention allows for the two-dimensional material to be protected during the fabrication of other layers during device fabrication, and protected until the point of use. For example, a sensor precursor may be manufactured and the molybdenum oxide layer etched shortly before use, exposing the pristine two-dimensional material below, reducing the risk of contamination through long-term storage. The precursor may be supplied with the appropriate region/window of molybdenum oxide exposed for etching, for example, to expose the predetermined sample surface between electrical contacts for a sensor. As discussed above, the method provides the additional benefit of improving the effectiveness of the functionalisation due to the reduced contamination from residues, which allows for an improved biosensor.

Accordingly, in some preferred embodiments, the method further comprises forming one or more further layers on the exposed portion of the two-dimensional material layer and/or forming one or more electrical contacts on the exposed portions of the two-dimensional material layer.

Electrical contacts may also, or instead, be deposited prior to the fourth step of etching the molybdenum oxide layer, but after the third step of patterning the first stack. In such embodiments, one or more contacts are formed in contact with an exposed edge of the two-dimensional material layer in each patterned second stack.

As such, in some embodiments it is preferred that the electronic device is a transistor;
wherein first and second electrical contacts (source and drain) are formed on the exposed portions of the two-dimensional material layer, each contacting adjacent edges of the two-dimensional material and molybdenum oxide layers;
and the method further comprises forming a third electrical contact (gate) on the stack between the first and second electrical contacts. Preferably the third contact is deposited on the patterned second stack since the third contact may then be formed at the same time as the first and second contacts. Alternatively, the third contact may be deposited on the first stack before patterning and forming the first and second contacts either side of the third contact after the patterning step.

The present invention finds a particular benefit for sensors, especially biosensors. As such, in some embodiments it is preferred that the electronic device is a sensor;
wherein first and second electrical contacts are formed in contact with opposite edges of the two-dimensional material and molybdenum oxide layers, and optionally on the exposed portions of the two-dimensional material (equivalent to the transistor above); and
and the method further comprises etching a window in the molybdenum oxide layer between the first and second electrical contacts thereby forming a sensor having an exposed sample surface of two-dimensional material for receiving a sample for testing. The step of etching a window may take place during (as part of) the fourth step described herein of etching the molybdenum oxide layer. Alternatively, the window may be etched after in a later step (for example where the first etch exposes a portion for forming contacts thereon and the window is etched shortly before use).

More preferably, the sensor is a biosensor and the method further comprises functionalising the exposed sample surface to form a biosensor having a functionalised sample surface for receiving a biological sample for testing.

In view of the foregoing description, a particularly preferred embodiment of the present method comprises:
(i) forming a graphene layer on a surface of a substrate by CVD;
(ii) forming a molybdenum oxide layer on the graphene layer to provide a first stack comprised of (preferably consisting of) the graphene and molybdenum oxide layers, the molybdenum oxide layer having a thickness of at least 0.1 nm;
(iii) patterning the first stack to provide one or more patterned second stacks on the substrate; and
(iv) etching at least a portion of the molybdenum oxide layer from one or more of the patterned second stacks to expose an underlying portion of the graphene layer.

A more preferred embodiment comprises:
(I) forming a graphene layer on a surface of a substrate by CVD;
(II) forming a molybdenum oxide layer on the graphene layer, the molybdenum oxide layer having a thickness of from 0.1 nm to 5 nm;
(III) forming a dielectric layer on the molybdenum oxide layer to provide a first stack comprised of (preferably consisting of) the graphene, molybdenum oxide and dielectric layers;
(IV) patterning the first stack to provide one or more patterned second stacks on the substrate; and
(V) etching at least a portion of the molybdenum oxide and dielectric layers from one or more of the patterned second stacks to expose an underlying portion of the graphene layer.

In accordance with a further aspect of the present invention, there is provided a two-dimensional material-containing substrate comprising, in order:
(a) a substrate;
(b) a two-dimensional material layer; and
(c) a patterned layer of molybdenum oxide exposing portions of the underlying two-dimensional material layer, the patterned layer of molybdenum oxide having a thickness of at least 0.1 nm;
wherein the exposed portions of the underlying two-dimensional material layer are devoid of organic polymer.

As described herein, it is also preferred that the two-dimensional material-containing substrate further comprises (d) a patterned layer of dielectric material on and across the patterned layer of molybdenum oxide.

Preferably, the two-dimensional material layer is a CVD grown graphene layer. The graphene being directly grown by CVD on the substrate therefore avoids physical transfer processing. The physical transfer of graphene, usually from copper substrates, introduces numerous defects which negatively impacts the physical and electronic properties of graphene. As such, a person skilled in the art can readily ascertain whether the graphene, and by extension a graphene-containing substrate is one comprising a CVD-grown graphene that has been grown directly on the substrate. This may be determined using conventional techniques in the art such as atomic force microscopy (AFM) and energy dispersive X-ray (EDX) spectroscopy. The two-dimensional material is devoid of metal (e.g. copper) contamination and devoid of organic polymer residues by virtue of the complete absence of contacting these materials with the two-dimensional material in the process. Furthermore, such transfer processes are generally not suitable for large scale manufacture (such as on silicon based substrates in fabrication plants). Unintentional doping, particularly from the catalytic metal substrates together with the etching solutions, also results in the production of graphene which is not sufficiently consistent from sample to sample as is required for commercial production.

As such, there is also provided a two-dimensional material-containing substrate obtainable by the method described herein.

In accordance with a further aspect, there is provided an electronic device comprising the two-dimensional material-containing substrate described herein, preferably a sensor, more preferably a biosensor. Such devices rely on the exposed (optionally functionalised) surface of a two-dimensional material for interacting with analytes of interest and it is highly beneficial that a device may comprise a patterned two-dimensional material having an exposed surface devoid of organic polymer.

As described herein in respect of the method, the exposed surface of two-dimensional material in a biosensor will be provided with appropriate functionalisation. That is, the biosensor has a functionalised sample surface for receiving a biological sample for testing, the functionalisation being chosen based on known chemistry to detect the presence of an analyte in a sample composition.

The method is particularly suitable for providing electrical contacts in contact with only an edge of the two-dimensional material (as opposed to on or above/below a surface thereof) such that this is a preferred arrangement of electrical contacts, though in other preferred embodiments, the contacts can be provided in contact with an edge and the adjacent upper surface. As will be appreciated, the contacts will be deposited at least on an adjacent surface of the substrate upon which the two-dimensional material is provided in order to contact an edge. In some embodiments, the molybdenum oxide layer and the further layer of dielectric material provided thereon can provide an effective barrier to electrically isolate the adjacent contacts from the analyte composition during testing. Therefore, in come embodiments, the patterned layer of dielectric material may also be provided on the contacts.

The relative arrangement of contacts at opposite sides of the sample surface serves to define a sample surface of the transducer (i.e. the two-dimensional material), for receiving an analyte composition therebetween the contacts. The two-dimensional material of a biosensor is optionally functionalised with a bioreceptor for detecting the presence of an analyte in a sample composition. An unfunctionalised sample surface can be used directly in sensors, or alternatively, the device may be functionalised by the user by treating the unfunctionalised sample surface with their bioreceptor of choice to produce a biosensor for the intended analysis at the point of, or shortly before, use (e.g. in diagnosis). Suitable reagents/compositions/materials and their methods for functionalising such samples surfaces are well-known in the art.

Preferably, the contacts each contact the patterned molybdenum oxide such that a sample surface is defined between portions of the molybdenum oxide (this may be between two isolated portions or ‘islands’ of molybdenum oxide adjacent opposite sides of the two-dimensional material, or a well in a continuous ‘ring’ of molybdenum oxide). An analyte composition is that which is to be tested and provides the analyte dispersed therein (typically a solution). For example, an analyte composition may be blood, saliva, urine, or a diluted solution thereof, especially for a biosensor. In the present invention, the contacts are provided on the same surface of the graphene as that which provides the sample surface. As will be appreciated, a sensor is for testing and detecting the presence of such an analyte and a lack of response will provide the user with a negative result indicating the lack of analyte in the sample composition being tested. Where the sample surface is functionalised, any appropriate functionalisation which provides an analyte-receptor immobilised on the two-dimensional material may be used. In other words, a functionalised two-dimensional material may be considered one comprising an analyte-receptor (or bioreceptor) immobilised on the exposed surface thereof.

Typically, a functionalised sample surface comprises an organic linker moiety which comprises two functional groups, a first of which serves to immobilise the analyte-receptor to the surface. For example, this may comprise non-covalent immobilisation through a pyrene functional group (particularly for graphene) or covalent immobilisation, such as through diazonium binding or alkylation of dopant atoms. The second functional group may comprise a thiol, amine or carboxylic acid functional group which is used to attach receptors, for example, biomolecules such as antibodies and aptamers. Functionalised surfaces may include inorganic compounds such as gold nanoparticles. Such components of a biosensor may also be referred to in the art as a bioreceptor.

The inventors have found that a sensor as described herein exhibits improved hysteresis, amongst other improvements in electronic properties, which can allow for quicker and more stable device measurements. This is key for accurate biosensing and determination of the presence or absence of analytes in a sample in order to allow for quick and accurate diagnosis. The use of molybdenum oxide as described herein as a sacrificial layer to deliver such improvements in a final electronic device is hitherto unknown.

In accordance with a further aspect, there is provided an array of electronic devices as described herein manufactured on a common substrate.

### FIGURES

The present invention will now be described further with reference to the following non-limiting Figures, in which:

FIG. 1 illustrates a method of patterning a stack by photolithography.

FIG. 2 illustrates a method of forming electrical contacts by photolithography.

FIG. 3 illustrates a method of forming a sensor.

FIG. 4 illustrates another method of forming a sensor.

FIG. 5 is a plan view of a sensor precursor manufactured by the methods illustrated in FIGS. 1 and 2 and in part by the method illustrated in FIG. 3.

FIG. 6 is a plan view of a graphene sensor manufactured by the methods illustrated in FIGS. 1 to 3.

FIG. 7 illustrates a method of functionalising the exposed sample surface of a graphene sensor.

FIG. 8 illustrates a method of testing for an analyte in a sample composition using a graphene biosensor.

FIG. 9 is a plan view of a graphene biosensor device in use, comprising a plurality of graphene biosensors on a common substrate which comprises a third electrical gate contact.

FIG. 10 is an I-V plot measuring the current (μA) against gate voltage (V) for exemplary graphene FETs manufactured using either an MoO₃ seed layer or an aluminium seed layer.

FIG. 11 is the plot measuring the transconductance (mS×sq./V) against gate voltage (V) for the same exemplary FETs measured in FIG. 10.

FIG. 12 is a box plot comparing the Dirac Point (V) of a plurality of exemplary FETs manufactured using either an MoO₃ seed layer or an aluminium seed layer.

FIG. 13 is a box plot comparing the Hysteresis (V) of the same exemplary FETs measured in FIG. 12.

FIG. 14 is a box plot comparing the transconductance (mS×sq./V) of the same exemplary FETs measured in FIGS. 12 and 13.

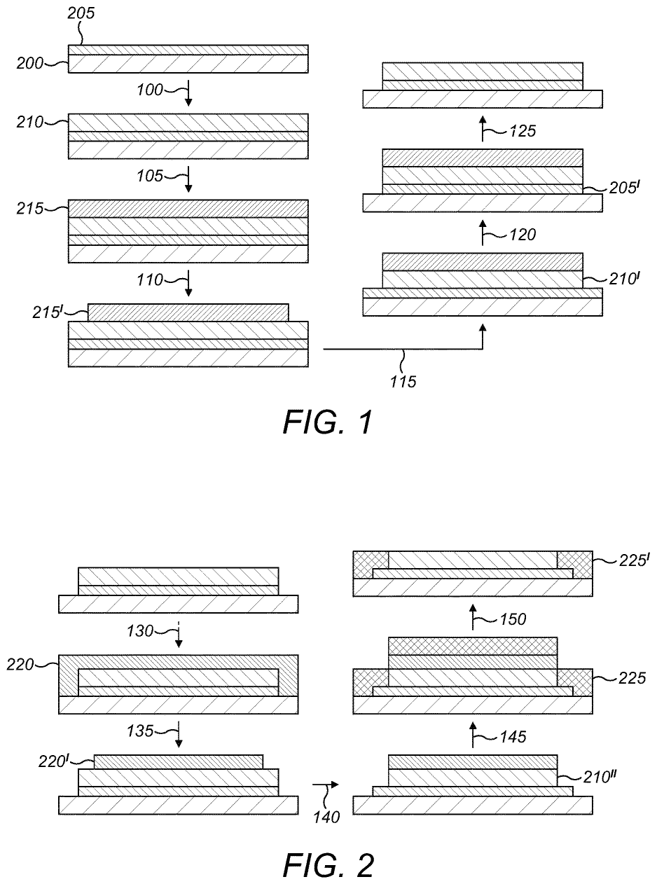

FIG. 1 illustrates an exemplary method of patterning graphene and a molybdenum oxide layer by photolithography. A graphene monolayer 205 (referred to throughout the Figures as graphene 205) is formed directly on a surface of a sapphire substrate 200 by CVD (not shown). A molybdenum oxide layer 210 is then formed in step 100 on the exposed surface of the graphene 205 and preferably, the layer 210 may further comprise a dielectric layer on the molybdenum oxide. A first photoresist 215 is applied in step 105 to the surface of the molybdenum oxide layer 210. Conventional photolithography materials and techniques may be used. Typically, a solution containing the photoresist materials is spin coated across the surface. The photoresist materials may comprise polymerisable material (e.g. methyl methacrylate) and patterned/masked UV light is used to cure and polymerise one or more portions of the photoresist materials so as to pattern the photoresist 215 and remove in step 110 the portions not exposed to UV light to provide a first masked region defined by the patterned photoresist 215′.

The exposed portion of the molybdenum oxide layer 210 is then etched in step 115 to retain only the molybdenum oxide layer 210′ beneath the first masked region. As a result, corresponding portions of the underlying graphene 205 are exposed which are then plasma etched in step 120 to retain only the graphene 205′ beneath the first masked region. Finally, the first patterned photoresist 215′ is removed by washing with a solvent to provide a patterned stack of molybdenum oxide 210′ on graphene 205′ on the substrate 200.

FIG. 2 illustrates an exemplary method of forming electrical contacts by photolithography. The method of FIG. 2 continues the method shown in FIG. 1. However alternative methods may be used to provide a patterned molybdenum oxide and graphene stack.

A second photoresist 220 is applied in step 130 to the surface of the molybdenum oxide layer 210′ and on adjacent portions of the substrate 200 which is then patterned in step 135 to provide a second masked region defined by the patterned second photoresist 220′ which exposes a portion adjacent the edge of the molybdenum oxide layer (and on opposite sides suitable for providing source and drain contacts on the underlying graphene). The second patterned photoresist 220′ also covers and protects regions of the substrate not adjacent to the stack (not shown). As described herein, first, second, third photoresists (and so forth) may each be applied and patterned using photolithography techniques known in the art. As for step 115, the patterned molybdenum oxide layer 210′ is again etched in step 140 to remove the exposed portions to retain only the molybdenum oxide layer 210″ beneath the second masked region exposing a pristine surface of the graphene 205′. Gold metal 225 is then deposited in step 145 using conventional e-beam methods thereby forming the first and second electrical contacts. The second patterned photoresist 220′ is then removed in a lift-off process which removes the gold 225 deposited thereon leaving the first and second electrical contacts 225′ on the surface of the previously exposed portion of graphene 205′.

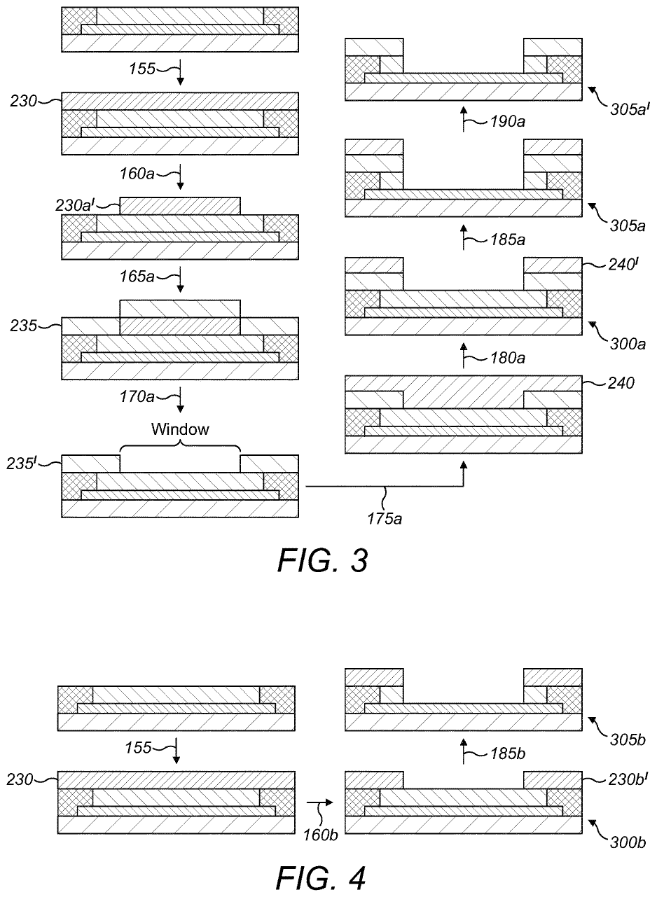

FIG. 3 illustrates an exemplary method of forming a sensor. A third photoresist 230 is applied in step 155 to the surface of the patterned stack 210″ and the electrical contacts 225′ and patterned in step 160a to provide a third masked region defined by the patterned third photoresist 230a′ which is preferably spaced apart from the first and second electrical contacts 225′, typically by at least 0.5 μm. A passivation layer 235 is then formed in step 165a across the stack. For example, an aluminium oxide layer 235 is formed by ALD in step 165a. The third patterned photoresist 230a′ is then removed in step 170a to expose a window of the patterned metal oxide layer 210″ leaving the patterned passivation layer 235′ on the first and second electrical contacts 225′ and adjacent portions of the molybdenum oxide layer 210″.

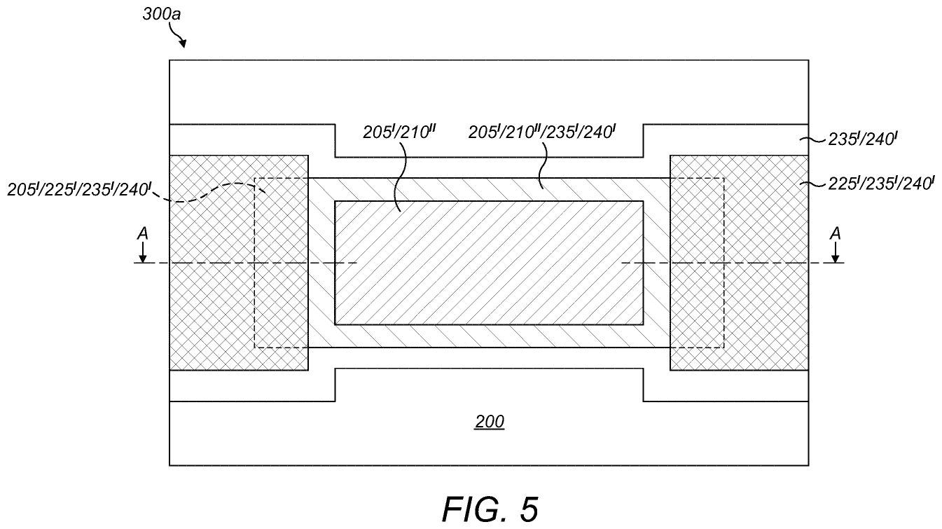

A fourth photoresist 240 is then applied in step 175a to the stack and patterned in step 180a to provide a patterned fourth photoresist 240′ as a mask on the patterned passivation layer 235′ to protect said layer and leaving the window exposed. The product is a suitable precursor 300a for completing the manufacture of a sensor shortly before use. FIG. 5 is a plan view of a precursor 300a with the layers of the precursor labelled with transparency to label the underlying layers for clarity. The cross-section A-A provides the cross section of precursor 300a as shown in FIG. 3.

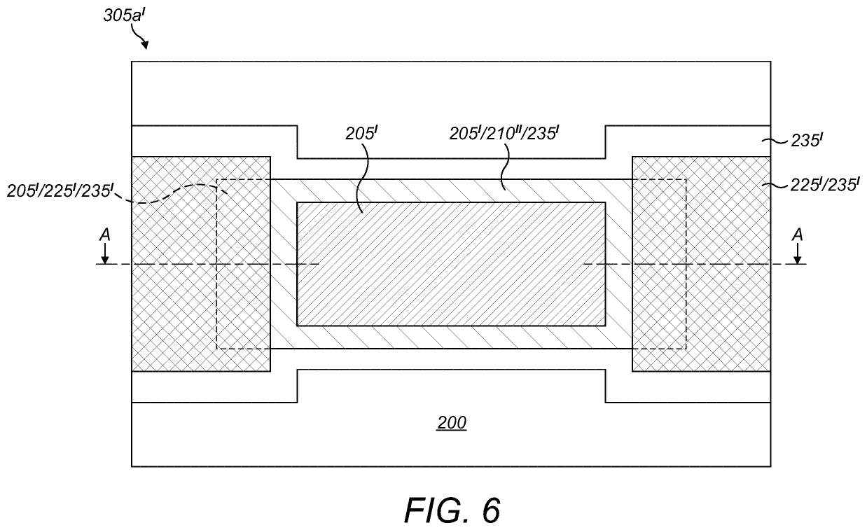

The uncoated window of the patterned molybdenum oxide layer 210″ is then etched in step 185a using deionised water or a dilute aqueous alkaline solution, such as a diluted solution of MF351 developer, to expose a surface of the underlying graphene 205′ thereby forming a graphene sensor 305a having an exposed sample surface. The patterned fourth photoresist 240′ of the graphene sensor 305a may be removed providing a graphene sensor 305a′. FIG. 6 is a plan view of a graphene sensor 305a′ with the layers of the precursor labelled with transparency to label the underlying layers for clarity. The cross-section A-A provides the cross section of sensor 305a′ as shown in FIG. 3.

FIG. 4 illustrates another exemplary method of forming a sensor. A third photoresist 230 is applied in step 155 to the surface of the patterned molybdenum oxide 210″ and the electrical contacts 225′ much like the first step in FIG. 3. The third photoresist 230 is then patterned in step 160b to provide a third masked region defined by the patterned third photoresist 230b′ (which therefore acts as a passivation layer) which is on and across the first and second electrical contacts 225′ and adjacent portions of the patterned molybdenum oxide layer 210″. As will be appreciated, the third masked region is equivalent to the pattern of the passivation layer produced in the method illustrated in FIG. 3.

The uncoated window of the patterned molybdenum oxide layer 210″ is then etched in step 185b using deionised water or a dilute aqueous alkaline solution to expose a surface of the underlying graphene 205′ thereby forming a graphene sensor 305b having an exposed sample surface.

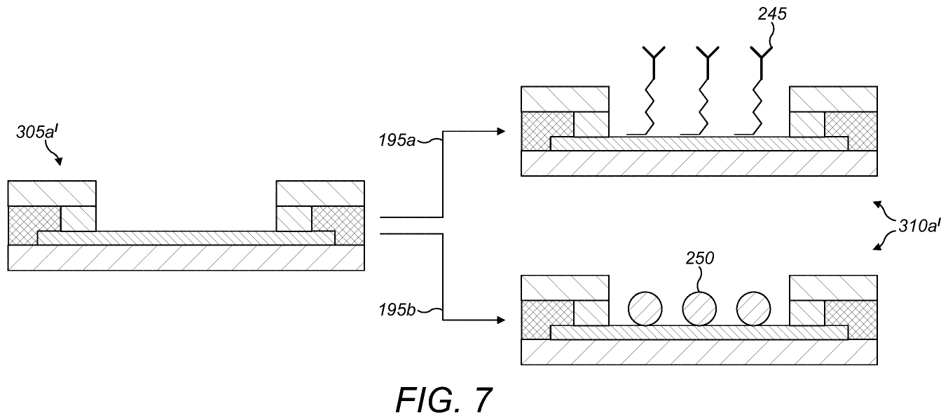

FIG. 7 illustrates two exemplary methods of functionalising the exposed sample surface of a graphene sensor 305a to provide a graphene sensor 310a′. In one method, graphene sensor 305a′ having an exposed unfunctionalised sample surface, as obtained by the methods shown in FIGS. 1 to 3, is functionalised in step 195a by immobilisation of a bioreceptor 245 onto the graphene surface. The bioreceptor 245 comprises a pyrene unit which serves as the anchor to the graphene surface by π-π stacking interactions and at the other end comprises an antibody suitable for binding an analyte of interest. In a second method, the graphene sensor 305a′ is functionalised in step 195b with metal nanoparticles 250.

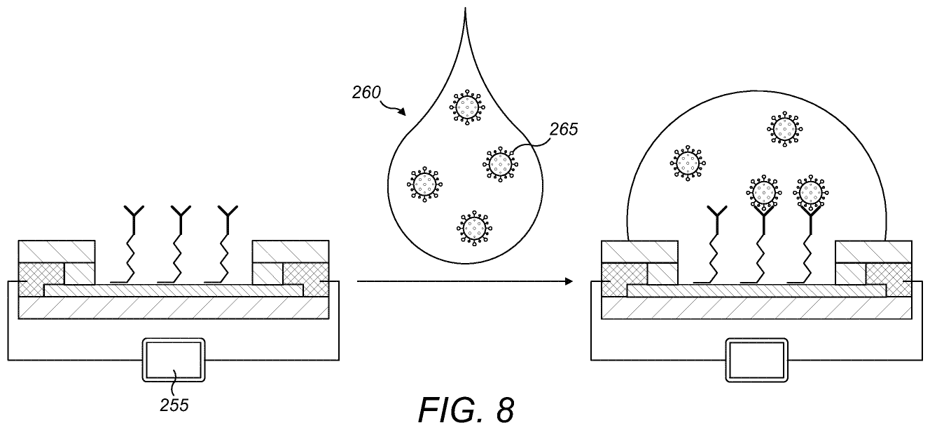

FIG. 8 illustrates a method of testing for an analyte in a sample composition using a graphene biosensor. A graphene biosensor 310a′ is wired via the first and second electrical contacts to a circuit.

The circuit comprises an integrated electronics and display 255 for processing the resulting signals and displaying the result of the test. A sample composition 260 for testing may or may not comprise the analyte of interest, such as a virus 265. The sample composition 260 (about 100 μL) is applied to the functionalised sample surface of the graphene biosensor 310a′ and does not contact the first or second electrical contacts 225′ due to the protective patterned passivation layer 235′ and remaining molybdenum oxide layer. The virus 265 binds with the antibody of the bioreceptor 245 causing a change in the electronic properties of the proximal graphene layer structure which in turn results in a modulation of the electronic signal which can be detected, processed and analysed to yield a result, e.g. a change in the Dirac point of the graphene 205′ whereby a predetermined change may be used to ascertain a positive or negative result for the test. The absence of organic polymer residues and other contaminants on the graphene surface allows for greater sensitivity and reliability.

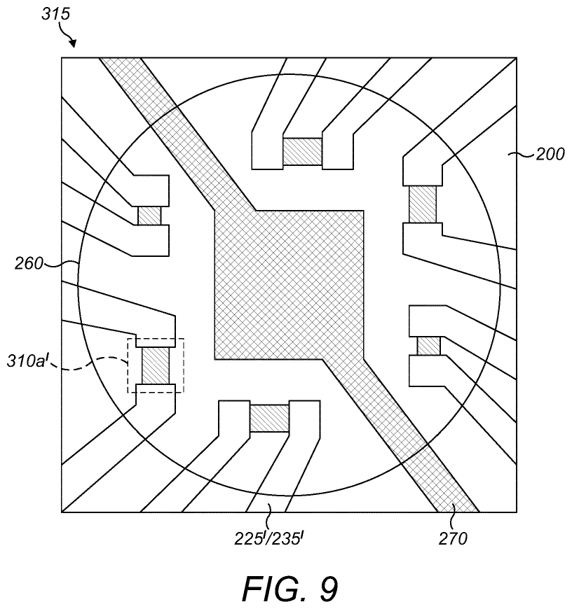

FIG. 9 is a plan view of a graphene biosensor device in use, comprising a plurality of graphene biosensors on a common substrate which comprises a third electrical gate contact 270. The graphene biosensor device 315 comprises a plurality of graphene biosensors 310a′ on a common substrate 200. Each graphene biosensor 310a′ may have the same or different functionalised surface. The device 315 further comprises a third electrical contact 270 which acts as a gate which may be formed and patterned during the same step(s) for the formation of the first and second electrical contacts 225/235′. In use, the sample composition 260 is applied to all of the graphene biosensors 310a′, simultaneously contacting the gate contact 270.

### EXAMPLES

The performance of MoO₃ as a water soluble seed layer forming part of a protective layer on top of a graphene biosensor was investigated by comparison with a 1 nm aluminium seed layer. Monolayer graphene was first grown on c-plane sapphire substrates in an MOCVD reactor and following this, 1 nm aluminium or 5 nm MoO₃ was deposited as a seed layer through e-beam evaporation. Each of these were followed by growth of an additional 20 nm of aluminium oxide (AlOx) by ALD. Biosensors/liquid gated graphene field effect transistor (FETs) were fabricated using photolithography. The final step in the device fabrication is the exposure of the graphene surface which is achieved by wet etching both the sacrificial AlOx and seed layers. For both 1 nm aluminium and 5 nm MoO₃ seed layer devices, the same NaOH etchant was used with the same dilution, etch duration and temperature.

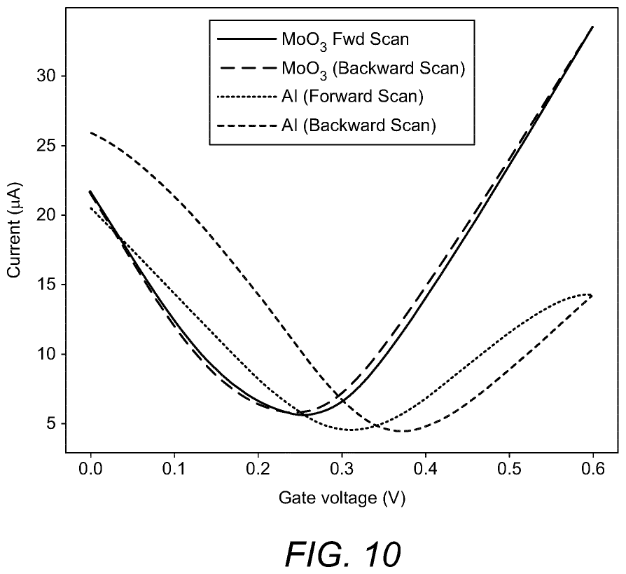

Following device fabrication, the FETs were soaked for 1 hour at room temperature in a conventional Phosphate Buffered Saline solution which is used in subsequent biofunctionalization steps. After soaking, the samples were rinsed with DI water and a 10 mM KCl solution was pipetted onto the FETs, and an Ag/AgCl gate electrode was immersed in the solution. For each device the I-V characteristic was measured by applying a 40 mV source-drain bias, whilst sweeping the gate voltage from 0 to 0.6 V. The gate voltage was swept in both forward and backward directions with a sweep rate of 22.5 mV/s. The results are shown in FIG. 10.

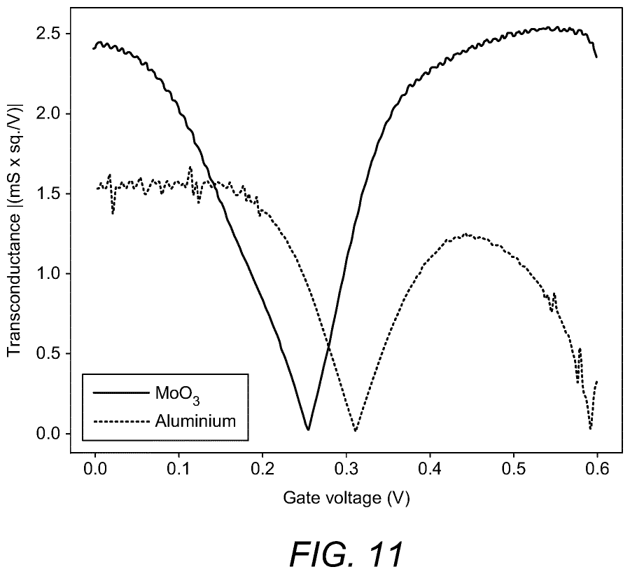

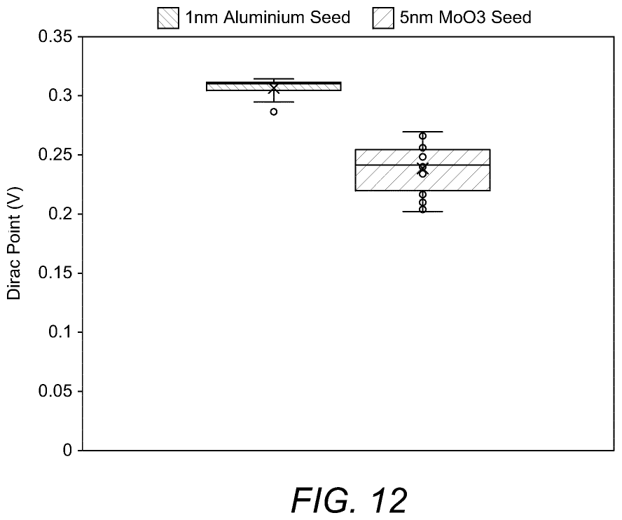

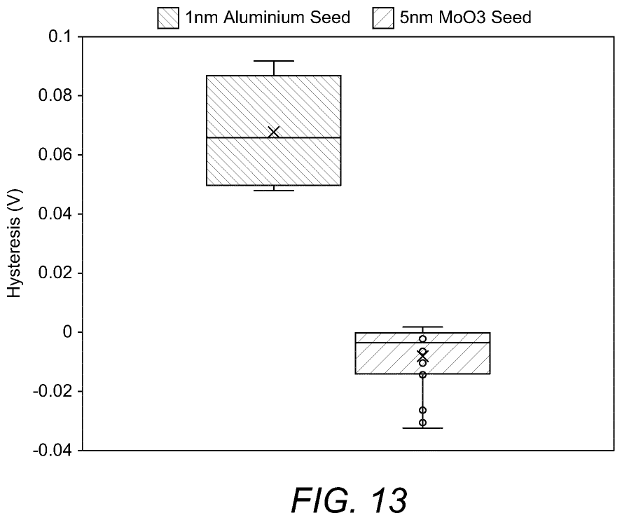

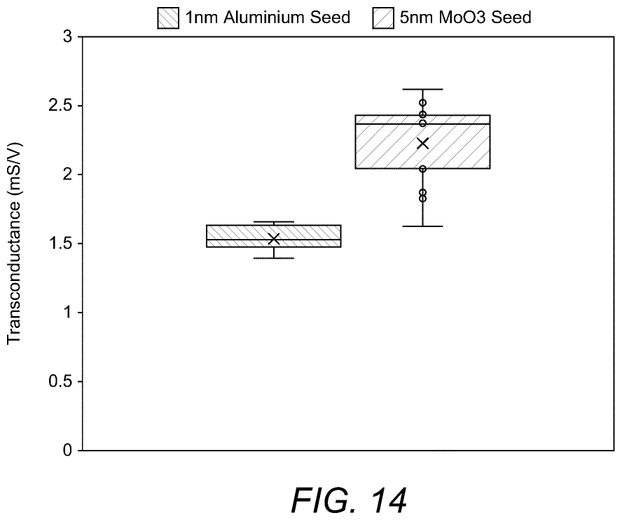

From the I-V characteristics, the Dirac point, transconductance and hysteresis were extracted and the results are shown in FIGS. 11 to 14. FIGS. 12 to 14 are box plots comparing the electrical performance of the two seed layers which uses data from 24 aluminium and 36 MoO₃ seed layer FETs. In each of FIGS. 12 to 14, the box plot for the aluminium seed FETs is shown on the left hand side and the box plot for the MoO₃ seed FETs is shown in the right hand side. The reasoning for the improved FET performance is the water soluble nature of the MoO₃ layer allows for a cleaner graphene interface after wet etching.

Comparison of liquid gated FET performance shows several differences:
Shift in MoO₃ seed devices Dirac point.
   Position of Dirac point related to potential surface cleanliness and subsequent biosensing performance.
Reduction in device hysteresis.
   Lower hysteresis allows for quicker and more stable device measurements.
Potentially higher transconductance.
   Higher transconductance should allow for more sensitive biosensing.

Conclusion: FETs fabricated with MoO₃ seed demonstrate improved performance likely to improve the reliability and sensitivity of a graphene biosensor.

As used herein, the singular form of “a”, “an” and “the” include plural references unless the context clearly dictates otherwise. The use of the term “comprising” is intended to be interpreted as including such features but not excluding other features and is also intended to include the option of the features necessarily being limited to those described. In other words, the term also includes the limitations of “consisting essentially of” (intended to mean that specific further components can be present provided they do not materially affect the essential characteristic of the described feature) and “consisting of” (intended to mean that no other feature may be included such that if the components were expressed as percentages by their proportions, these would add up to 100%, whilst accounting for any unavoidable impurities), unless the context clearly dictates otherwise.

It will be understood that, although the terms “first”, “second”, etc. may be used herein to describe various elements, layers and/or portions, the elements, layers and/or portions should not be limited by these terms. These terms are only used to distinguish one element, layer or portion from another, or a further, element, layer or portion. It will be understood that the term “on” is intended to mean “directly on” such that there are no intervening layers between one material being said to be “on” another material. Spatially relative terms, such as “under”, “below”, “beneath”, “lower”, “over”, “above”, “upper” and the like, may be used herein for ease of description to describe one element or feature's relationship to another element(s) or feature(s). It will be understood that the spatially relative terms are intended to encompass different orientations of the device in use or operation in addition to the orientation depicted in the figures. For example, if a device as described herein is turned over, elements described as “under” or “below” other elements or features would then be oriented “over” or “above” the other elements or features. Thus, the example term “under” can encompass both an orientation of over and under. The device may be otherwise oriented and the spatially relative descriptors used herein interpreted accordingly.

It will also be understood that the terms “region”, “portion”, etc. may be used herein to describe one or more regions or portions such that a region or a portion may be a single continuous region or portion or a discontinuous region or portion (for example in the manufacture of a plurality or an array of separate devices on a common substrate).

The foregoing detailed description has been provided by way of explanation and illustration, and is not intended to limit the scope of the appended claims. Many variations of the presently preferred embodiments illustrated herein will be apparent to one of ordinary skill in the art, and remain within the scope of the appended claims and their equivalents.

1. A method of patterning a two-dimensional material for use in the manufacture of an electronic device, the method comprising:
(i) providing a two-dimensional material layer on a surface of a substrate;
(ii) forming a molybdenum oxide layer on the two-dimensional material layer to provide a first stack comprised of the two-dimensional material and molybdenum oxide layers, the molybdenum oxide layer having a thickness of at least 0.1 nm;
(iii) patterning the first stack to provide one or more patterned second stacks on the substrate; and
(iv) etching at least a portion of the molybdenum oxide layer from one or more of the patterned second stacks to expose an underlying portion of the two-dimensional material layer.

2. The method according to claim 1, wherein the two-dimensional material layer is provided on the surface of the substrate in step (i) by directly forming the two-dimensional material layer on the surface.

3. (canceled)

4. The method according to claim 1, wherein the molybdenum oxide layer has a thickness of at most 100 nm.

5. The method according to claim 1, wherein the first stack has a thickness of at least 5 nm, and/or at most 100 nm.

6. The method according to claim 1, further comprising forming one or more further layers on the exposed portion of the two-dimensional material layer.

7. The method according to claim 1, further comprising forming one or more electrical contacts on the exposed portions of the two-dimensional material layer.

8. The method according to claim 1, further comprising forming one or more electrical contacts on the substrate between steps (iii) and (iv), each in contact with an edge of the two-dimensional material layer in each patterned second stack.

9. The method according to claim 1, wherein the electronic device is a transistor;
wherein first and second electrical contacts are formed on the exposed portions of the two-dimensional material layer, each contacting adjacent edges of the two-dimensional material and molybdenum oxide layers;
the method further comprising forming a third electrical contact on the stack between the first and second electrical contacts.

10. The method according to claim 1, wherein the electronic device is a sensor;
wherein first and second electrical contacts are formed in contact with opposite edges of the two-dimensional material and molybdenum oxide layers, and optionally on the exposed portions of the two-dimensional material; and
wherein the method comprises etching a window, during or after step (v), in the molybdenum oxide layer between the first and second electrical contacts thereby forming a sensor having an exposed sample surface of two-dimensional material for receiving a sample for testing.

11. The method according to claim 10, wherein the sensor is a biosensor, the method further comprising functionalising the exposed sample surface to form a biosensor having a functionalised sample surface for receiving a biological sample for testing.

12. The method according to claim 1, wherein the first stack is patterned using photolithography.

13. The method according to claim 1, wherein the molybdenum oxide layer is etched using an aqueous solution.

14. The method according to claim 13, wherein the aqueous solution comprises an alkali metal hydroxide.

15. The method according to claim 1, wherein, between steps (ii) and (iii) of forming the molybdenum oxide layer and patterning the first stack, the method further comprises forming a dielectric layer on the molybdenum oxide layer to provide a first stack comprised of the two-dimensional material, molybdenum oxide and dielectric layers.

16. The method according to claim 1, wherein the entirety of the molybdenum oxide and optional dielectric layers are etched away.

17. (canceled)

18. A two-dimensional material-containing substrate comprising, in order:
(a) a substrate;
(b) a two-dimensional material layer; and
(c) a patterned layer of molybdenum oxide exposing portions of the underlying two-dimensional material layer, the patterned layer of molybdenum oxide having a thickness of at least 0.1 nm;
wherein the exposed portions of the underlying two-dimensional material layer are devoid of organic polymer.

19. An electronic device comprising the two-dimensional material-containing substrate of claim 18.

20. The electronic device according to claim 19, wherein the electronic device is a biosensor.

21. The electronic device according to claim 20, wherein the exposed portions of the underlying two-dimensional material layer are functionalised with a bioreceptor for detecting the presence of an analyte in a sample composition.

22. An array of electronic devices manufactured on a common substrate, wherein each of the electronic devices are in accordance with claim 19.
